(19) United States
(12) Patent Application Publication
(10) Pub. No.: US 2025/0183336 A1
(43) Pub. Date: Jun. 5, 2025

(54) METHOD FOR MONITORING A BATTERY POWER PLANT

(71) Applicant: LIVA Power Management Systems GmbH, Frankfurt am Main (DE)

(72) Inventors: Yifeng Li, Steinheim (DE); Jens Kaufmann, Freiburg (DE); Thomas Lüth, Freiburg (DE)

(21) Appl. No.: 18/844,891

(22) PCT Filed: Feb. 22, 2023
(86) PCT No.: PCT/EP2023/054417

§ 371 Date: Sep. 6, 2024

(30) Foreign Application Priority Data
Mar. 8, 2022 (DE) 10 2022 105 462.4

(51) Int. Cl. H01M 8/04537; H01M 8/0432; H01M 8/0438; H01M 8/18

(52) U.S. Cl. CPC H01M 8/04559; H01M 8/04365; H01M 8/0438; H01M 8/04589; H01M 8/04619; H01M 8/04649; H01M 8/188

(57) ABSTRACT

The present invention provides a method for monitoring a battery power plant comprising a plurality of battery modules which are designed as a redox flow battery, and wherein the method comprises the following steps:
S1: generating a time-varying excitation current I with a base frequency f, by means of which at least one battery module is excited to perform an impedance spectroscopy;
S2: time-resolved detecting the excitation current I and a response voltage V;
S3: calculating the impedance Z(ω), wherein ω=2πf;
   and wherein the method comprises the following step:
S4: initiating maintenance work on the at least one battery module if Re{Z(ω)} exceeds a predefined limit value,
   and wherein in step S1 the excitation current I is generated by use of a converter, wherein the base frequency of the generated time-varying excitation current is f≤20 Hz.

### TECHNICAL FIELD

The invention relates to a battery power plant comprising a plurality of separate battery energy storage units or battery modules which are electrically connected to one another in order to receive or output electrical energy. The invention relates to a battery power plant comprising battery energy storage units which are designed as redox flow batteries.

### BACKGROUND

Such battery power plants comprising a plurality of separate battery energy storage units, which are also referred to as battery modules, are known from the prior art. For example, WO 2014/170373 A2 discloses an example of a battery power plant comprising several battery strings connected in parallel, wherein the battery strings each comprise several direct current battery modules connected in series. The battery modules in a battery power plant can be connected in series and in parallel in various ways depending on the application.

In order to ensure long-term undisturbed operation of such a battery power plant, it is advantageous if the individual battery energy storage units can be monitored in order to detect a malfunction or failure of the battery energy storage units at an early stage.

US 2018/0175429 A1 discloses a system and a method for detecting faults in redox flow batteries. The faults to be detected are leaks in the electrolyte tanks, which are detected with the aid of capacitively operating sensors.

KR 10-2019-0072790 A discloses a device and a method for determining the service life of a battery. Here, an impedance measurement method is used, which is known by the abbreviation EIS (“Electrochemical Impedance Spectroscopy”). A special device is connected to the electrical terminals of the battery to determine the impedance spectrum. The device includes inter alia a waveform generator, a measuring circuit and a microcontroller.

### SUMMARY

The inventors have recognized that the method known from KR 10-2019-0072790 A is in principle suitable for monitoring the state of the redox flow type battery energy storage unit of a battery power plant. However, the following difficulties arise. Connecting the measuring device to the individual battery energy storage units is very complex, considering that such a battery power plant usually comprises a large number of battery energy storage units. Another possibility would be to equip each battery energy storage system with a corresponding measuring device, which forms an integral part of the respective battery energy storage unit, so to speak. This solution would significantly increase the production costs of the battery power plant.

It is the object of the invention to provide a method for monitoring the battery energy storage unit of a battery power plant, which at least partially overcomes the disadvantages mentioned above.

According to the invention, the object is achieved by an embodiment according to the independent claim. Further advantageous embodiments of the present invention can be found in the dependent claims.

### BRIEF DESCRIPTION OF DRAWINGS

In the following, the invention is explained with reference to figures. The figures show in detail:

FIG. 1 Battery module of the redox flow type;

FIG. 2 Electrical structure of a battery power plant;

FIG. 3 Signal forms of the excitation current;

FIG. 4 Nyquist diagram; and

FIG. 5 Flow chart of the method according to the invention.

### DETAILED DESCRIPTION

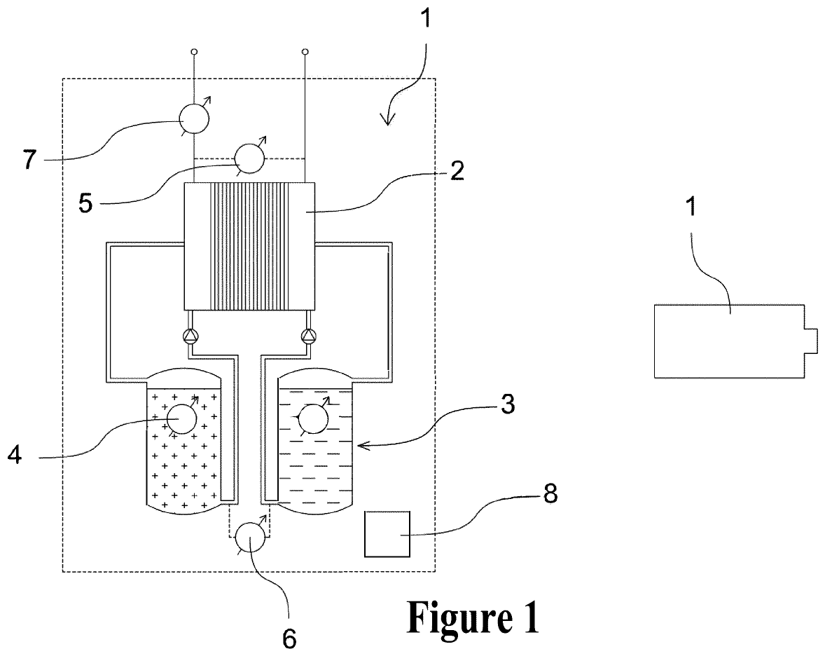

FIG. 1 shows a schematic representation of a redox flow type battery module on the left side. The battery module is designated with 1. The battery module comprises a cell arrangement designated with 2 and a tank device designated with 3. The cell arrangement 2 is an arrangement of a plurality of redox flow cells, which can be arranged as desired. For example, it could be a single cell stack (i.e. a series connection of several redox flow cells), a series connection of several stacks, a parallel connection of several stacks or a combination of series and parallel connections of several stacks. The tank device 3 is used to store the electrolyte and to supply the cell arrangement 2 with electrolyte. With a few exceptions, the tank device 3 comprises at least two tanks, a pipe system for connecting the tanks to the cell arrangement 2 and pumps for supplying the electrolyte. FIG. 1 shows two separate pumps. The electrolyte could just as well be supplied by use of a double-head pump, i.e. with two pumps that are driven by a common motor. Here, the tank device 3 is designed in such a way that it can supply all cells of the cell arrangement 2 with electrolyte. Thus, if the pumps supply the electrolyte, it flows through all cells of the cell arrangement 2.

The battery module 1 optionally comprises at least one temperature sensor, which is arranged in such a way that it can detect an electrolyte temperature. FIG. 1 shows two such sensors, one of which is designated with 4. In the embodiment shown in FIG. 1, the temperature sensors 4 are arranged in the tank device 3. However, they could just as well be arranged at any other suitable location in the battery module 1 where they are able to detect an electrolyte temperature.

The battery module 1 further comprises at least one further sensor. This sensor is designed in such a way that it can measure the so-called open circuit voltage (OCV). The OCV value is a measure of the state of charge (SoC) of the battery module. The sensor for measuring the open circuit voltage is designated with 6. Another optional sensor is designed in such a way that it can measure the terminal voltage of the cell arrangement 2 and thus also of the battery module 1. When charging or discharging the battery module 1, the terminal voltage differs from the open-circuit voltage by the voltage that drops across the internal resistance of the cell arrangement 2. The sensor for measuring the terminal voltage is designated with 5. A further optional sensor is designed so that it can measure the current through the battery module 1. The sensor for measuring the current through the battery module 1 is designated with 7. Optionally, the battery module 1 also comprises an evaluation device designated with 8.

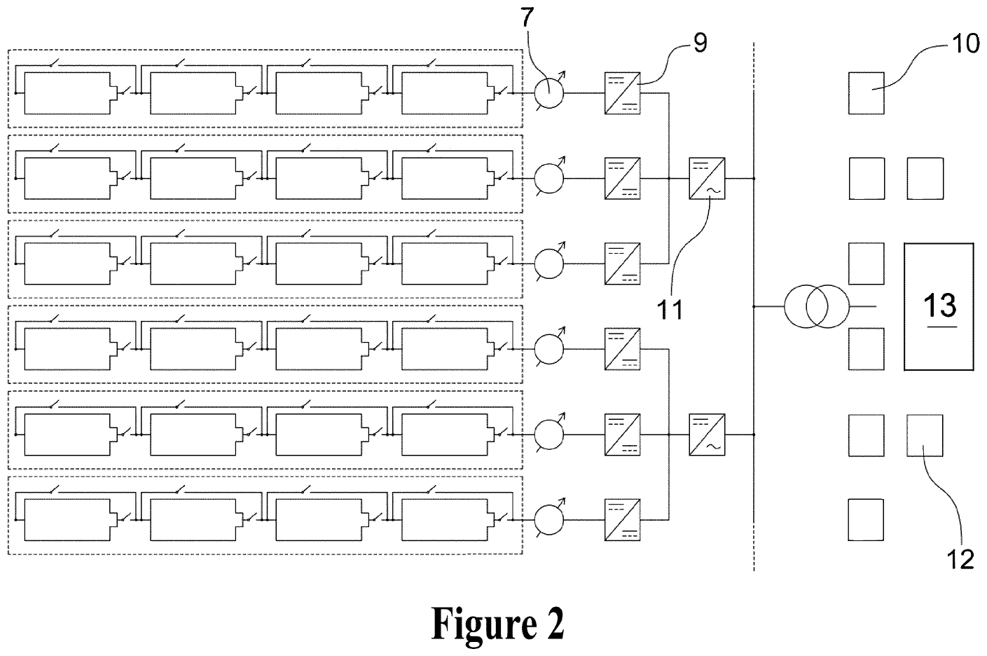

FIG. 2 shows a possible implementation of the electrical structure of a battery power plant in a very simplified form. Battery strings with a series connection of battery modules are indicated on the left side. A battery string can comprise a single battery module or several battery modules connected in series. Each battery string is surrounded by a dashed rectangle. Each battery module of a battery string can optionally be switched into or out of the battery string by use of a pair of switches. Each battery string is connected to a DC-DC converter. One of the DC-DC converters is designated with 9. Each of the battery strings optionally comprises a sensor for measuring the current flowing through the battery string. One of these sensors is designated with 7. Since the current flowing through the battery string must also flow through each battery module of the same battery string, the current can be measured by a sensor 7 outside the battery modules 1, as shown in FIG. 2, or by sensors 7 inside the battery modules 1, as shown in FIG. 1. Several battery strings are each connected to each other via DC busbars and thus each form a battery string group. Here, the DC-DC converters are each arranged between the associated DC busbar and the battery strings. Each battery string group is connected to the AC busbars of the battery power plant via a DC-AC converter. One of the DC-AC converters is designated with 11. In FIG. 2, three battery strings respectively form a battery string group. However, the number of battery strings per battery string group can be arbitrary and depends only on the performance of the DC-AC converters used and the rated power of the battery strings. The AC busbars are connected to the transmission grid via a transformer. If a battery string group comprises only one string, the relevant DC-DC converter 9 can be omitted.

The DC-DC converters 9 and the DC-AC converters 11 are used to feed a current into the battery modules 1 connected to them in order to charge or discharge the battery modules 1.

The right side of FIG. 2 shows an example of a control structure suitable for such a battery power plant. Each battery string has its own control unit, one of which is designated with 10. Each battery string group in turn has its own control unit, one of which is designated with 12. The central control unit associated to the battery power plant is designated with 13. Here, the subordinate control units 10 and 12 can be implemented separately or integrated into the control means associated to the central control unit. The subordinate control units 10 and 12 could just as well be implemented integral and the central control unit 13 separate. If a battery string group comprises only one string, then this battery string group requires only one control unit, i.e. one of the associated control units 10 or 12 can be omitted.

The inventors have recognized that the elements of a battery power plant described in the preceding sections can be used to realize a rudimentary state monitoring by means of an impedance measurement method. This means that the state of the battery modules can be monitored without having to connect a special device to the battery modules.

If this rudimentary state monitoring detects an abnormality in one or more battery modules of a battery string, either maintenance of the battery modules concerned or a more detailed examination of their state can be carried out.

To describe the method according to the invention, the basic steps that are usually carried out to determine impedance spectra are first explained here. In impedance spectroscopy, the electrical arrangement is regarded as a system whose characteristics are to be determined. This is implemented by exciting with a defined input signal, while the output signal is measured as the system response. This can be done by injecting a current I while simultaneously measuring the voltage V that drops across the electrical arrangement. The injected current I serves as the excitation of the electrical system. The voltage V represents the response signal of the electrical system. Conversely, the system can also be excited by applying a voltage V, while the current I is measured as the system response. The method is described below by use of the first variant as an example, wherein the relationships also apply to the second variant. The basic principle of spectroscopy is that the system is excited with signals of different frequencies, which are detected time-resolved just as the associated response signal. The impedances of the system at the frequencies used for excitation can then be calculated from the excitation and output signals by use of mathematical methods.

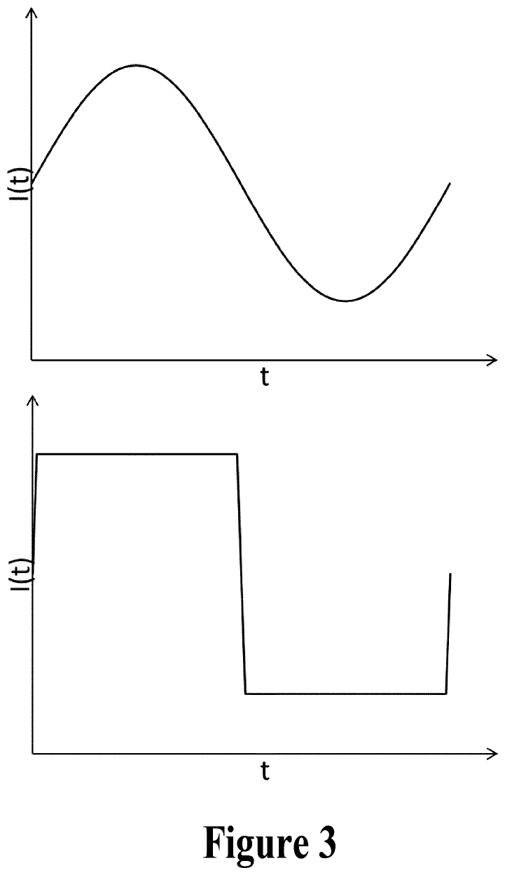

In impedance spectroscopy, there are generally several possibilities for signal forms with which the system can be excited. Usually sinusoidal signals are used, as shown in the upper part of FIG. 3. When exciting the system with such a signal, the impedance can be calculated at the exact frequency of the sinusoidal signal. The signal is usually fed in over several periods. In order to determine impedances at other frequencies and thus an impedance spectrum, measurements at these frequencies must also be carried out individually in succession. An alternative option is to feed in signals that include components of several frequencies. For example, a signal shape that follows a so-called square wave function, as shown in the lower part of FIG. 3, is suitable for this purpose. In contrast to a sinusoidal wave signal, a square wave signal includes further frequency components at the odd harmonics of the base frequency in addition to the base frequency. If a system is now excited with a square wave signal, both the excitation signal and the response signal include signal components at several frequencies. This means that not only the impedance value associated with the base frequency of the square wave function can be determined, but also other impedance values that are associated to the frequencies that correspond to the higher orders of the base frequency. In practice, the number of higher orders to be detected is limited by the finite edge steepness of the rectangular function of the excitation current, by the finite sampling rate of current and voltage and by superimposed interference signals.

In principle, even an arbitrarily time-varying excitation signal can be used, i.e. even a signal that is not periodic. According to Fourier theory, such a signal can be regarded as a superposition of periodic functions. The base frequency results in 1/T (or 2π/T), wherein T is the temporal length of the signal. In practice, however, the signal shapes shown in FIG. 3 are usually used. Excitation with individual rectangular pulses or step functions is also practicable. With periodic signals, the base frequency is of course given by 1/T₀ (or 2π/T₀), where T₀ is the period.

The result of impedance spectroscopy is the impedance Z of the electrical arrangement as a function of the frequency f or the angular frequency ω=2πf: Z(ω). Here, Z(ω) is a function in the space of imaginary numbers and includes information about the magnitude and phase of the impedances. In the case of pure-frequency excitation with a sinusoidal signal, ω results directly from the frequency of the excitation current. The magnitude of the impedance at this frequency is calculated from the quotient of the magnitudes of the sinusoidal voltage signal and the current signal, while the phase is calculated from the difference between the phases of the two signals.

For an excitation current that includes higher frequencies in addition to the base frequency, both the detected excitation current I and the detected response signal V are subjected to a Fourier transformation, and F{I}(ω) and F{V}(ω) are obtained. The required impedance function Z(ω) then results in Z(ω)=F{V}(ω)/F{I}(ω). Here, it is clear that Z(ω) is only defined for frequencies ω for which F{I}(ω) is not zero. It should also be mentioned that for the impedance spectroscopy of batteries, the time-resolved response signal of the terminal voltage must still be corrected by the open-circuit voltage, so that the voltage drop across the internal resistance of the battery results, i.e. V=V_{Klemm}−V_{OCV}.

The representation of Z(ω) can be advantageously in the form of a so-called Nyquist diagram. The real part of Z(ω) is plotted in the x-direction and the negative imaginary part of Z(ω) is plotted in the y-direction. The unit of Z(ω) is ohm.

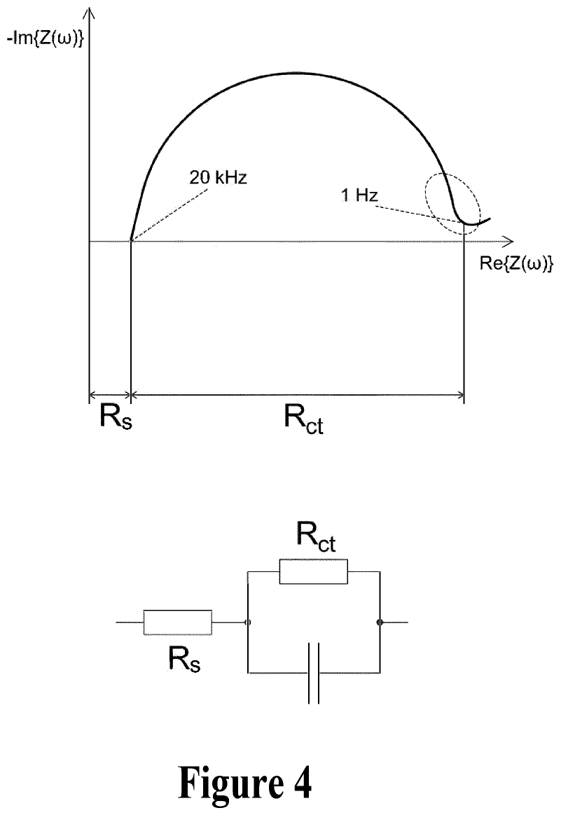

The upper part of FIG. 4 shows a typical Nyquist diagram of a redox flow battery in a qualitative form. The lower part of FIG. 4 shows a simplified equivalent circuit diagram, which is used to interpret the Nyquist diagram shown above. Two resistance values can be derived from the diagram: Rₛ and R_{ct}. Rₛ is interpreted as the static internal resistance component, which is given, for example, by the resistance of the contacts and the leads, while R_{ct} describes the component resulting from the kinetics of the charge transfer between electrode and electrolyte. It is clear from the equivalent circuit diagram that Rₛ contributes to the total resistance regardless of the frequency, while the contribution of R_{ct} is reduced at high frequencies by the parallel double-layer capacitance and therefore only makes a significant contribution at low frequencies. Typically, Rₛ is roughly readable in the Nyquist diagram at frequencies of about 20 kHz, while Rₛ+R_{ct} can be plotted at frequencies around 1 Hz. Due to the parasitic influence of a serial inductance (not shown in the diagram), e.g. by the leads, the Nyquist diagram is shifted in the direction of the positive imaginary axis (i.e. downwards). This also changes the point of intersection with the x-axis. Rₛ can therefore only be determined approximately graphically. More precise results can be obtained by the mathematical fit of an equivalent circuit model. In the following, the sum Rₛ+R_{ct} is referred to as the “total internal resistance”, even if this does not correspond exactly to the DC resistance.

The inventors have recognized that by use of he DC-DC converters 9 or by use of the DA-AC converters 11 a time-variable excitation current I can be generated in a battery power plant, with which the associated battery modules can be excited for rudimentary impedance spectroscopy. The rise times of the excitation current are limited by the power electronics, such that only signals up to a certain upper frequency limit can be generated with acceptable quality. When using an excitation signal with different frequency components such as the square wave signal, the number of calculable frequency components above the base frequency is also limited by the signal quality and the accuracy of the measuring device. Even if it is therefore not possible to obtain a high-quality impedance spectrum up to high frequencies in the kHz range, information about the behavior at low frequency is still available in sufficient quality. This is sufficient to determine the sum Rₛ+R_{ct}. Since degradation processes of redox flow batteries often lead to increased contact resistances or to deteriorated charge transfer processes, an increased value of the sum Rₛ+R_{ct} is then obtained, which can be determined by use of the method according to the invention. The method according to the invention is therefore suitable for identifying battery modules that suffer from the aforementioned problems. Further, more complex investigations can then be carried out on the battery modules identified in this way in order to solve the problems.

The inventors have recognized that it is basically sufficient to determine a single Z(ω) value in the frequency range≤20 Hz in order to obtain an initial indication of possible problems with the battery modules under investigation. If the total internal resistance of a battery module increases, then the entire edge of the Nyquist graph marked with the dashed ellipse shifts to higher abscissa values (Re{Z(ω)}), so that increased abscissa values can also be detected at any frequency in this range.

Of course, several Z(ω) values can also be determined at different low frequencies (≤20 Hz) in order to increase the significance of the measurement. In this case, the determined impedances can also be fitted with a suitable model before comparison with the predefined limit value described below in order to further increase the significance of the measurement.

As already mentioned above, the method according to the invention is described below and in the claims for the case that a current signal is used for excitation. However, this is not to be regarded as limiting and also includes the case where a voltage signal is used for excitation.

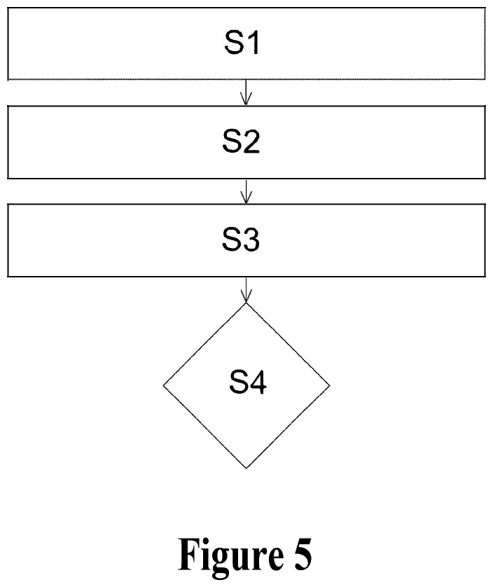

The steps of the method according to the invention are shown in FIG. 5. The method comprises at least the following steps:
S1: Generation of a time-varying current I with a base frequency ω, with which at least one battery module 1 is excited to perform an impedance spectroscopy;
S2: Time-resolved detection of the excitation current I and a response voltage V;
S3: Calculation of the impedance Z(ω);
S4: Initiation of maintenance work on the at least one battery module 1 if Re{Z(ω)} exceeds a predefined limit value.

Here, in step S1, the current I is generated by use of a DC-DC converter 9 or, if the associated battery string group comprises only one battery string, by use of an AC-DC converter 11, wherein the base frequency of the generated time-varying current is f=ω/2π≤20 Hz.

The predefined limit value is set in such a way that Re{Z(ω)} for f=ω/2π≤20 Hz of any “healthy” battery module of the battery power plant is below the limit value. For example, a random sample of “healthy” battery modules can be measured by use of impedance spectroscopy. The limit value is then selected so that all Re{Z(ω)} for f=ω/2π≤20 Hz of the measured battery modules are clearly below the limit value (i.e. with regard to the measurement accuracy and the dispersion of the Re{Z(ω)} of the measured battery modules).

In the following, the term “converter” refers to both a DC-DC converter 9 and an AC-DC converter 11. Such a converter approximates a time-variable current curve on the DC side by use of discrete steps. Therefore, even a sinusoidal current curve as shown in the upper part of FIG. 3 will not represent a single frequency. It is therefore recommended to apply a Fourier transformation to the signals detected in step S2 in any case, even if a sinusoidal signal is used.

If the open-circuit voltage of the battery module remains constant or can be assumed to be constant during the execution of the method according to the invention, then it does not need to be detected during the execution of the method according to the invention because it only changes the DC component of the impedance and thus does not contribute to Re{Z(ω)} for ω≠0. However, if the open-circuit voltage changes over time during the execution of the method according to the invention, it should be detected in a time-resolved manner in step S2 and used in the calculation of Z(ω) in step S3 as described above (i.e. V=V_{Klemm}−V_{OCV}).

Since the internal resistances of the at least one battery module under investigation depend on the temperature of the electrolyte and the flow rate of the electrolyte through the cell arrangement, it is advantageous to also detect these variables during the execution of the method according to the invention and to include them in step S4. It is particularly advantageous if the state of charge (SoC) is also detected and included in step S4. This can be done, for example, by predefining a function of limit values instead of a single limit value for the real part of the impedance, wherein this function depends on the temperature, flow rate and SoC. These variables can just as well be used to mathematically correct the determined total internal resistance (Re{Z(ω)}) and to make the initiation of maintenance work dependent on the total internal resistance corrected in this way.

The rotational speed or the power consumption of the pumps can also be used as a measure of the flow rate of the electrolyte through the cell arrangement.

With the method according to the invention, all battery modules of a battery string can be monitored simultaneously, because the excitation current generated by the converter flows through all modules of the battery string. There are various options for detecting and evaluating the excitation current and the response voltage. The first option is to detect the two variables mentioned at string level. The current sensor 7 shown in FIG. 2 and a voltage sensor not shown are used for this purpose. As a rule, suitable converters in question include a suitable voltage sensor that is integrated into the converter. The control units 10 and 12 can be used to evaluate or calculate the impedance Z(ω). This can then be used to determine the impedance of the entire battery string.

A second possibility is that the two variables mentioned are recorded at battery module level. The sensors 5 and 7 shown in FIG. 1 are used for this purpose. The evaluation device 8 can then be used to evaluate or calculate the impedance Z(ω), for example.

Another possibility is that the excitation current is detected at string level, i.e. by use of the sensor 7 of FIG. 2, and the response voltage of the battery modules is detected at module level by use of sensor 5 of FIG. 1. In this case, the measurement signals detected in this way must be synchronized. The control units 10 and 12 or the evaluation device 8 can be used to evaluate or calculate the impedance Z(ω).

The latter two methods can be used to determine the impedances of individual battery modules.

The open-circuit voltage, if it is to be detected, is detected at battery module level by use of the sensor 6. Synchronization of the detected open-circuit voltage with the other signals is only necessary if the open-circuit voltage is to be detected with temporal resolution. Otherwise, it is usually only used to determine SoC.

If the monitored battery string comprises the switch pairs shown in FIG. 2, moreover, any subset of the battery modules associated to the battery string can be connected to the converter and monitored by use of the method according to the invention.

The data obtained with the method according to the invention can be stored and managed in the central control unit of the battery power plant.

Several possible maintenance works are possible in step S4. For example, the battery module(s) in question could be subjected to a full impedance spectroscopy by use of a suitable device to verify the data obtained by use of the method according to the invention and to obtain further information, e.g. the separate values of Rₛ and R_{ct}. This would allow the state and a potential problem of the battery module to be diagnosed more accurately. It would also be possible to replace the cell arrangements in the battery modules in question and then further examine and, if necessary, repair or dispose the removed cell arrangements.

The method according to the invention enables to monitor the battery modules by use of the components (converter 9 or 11, sensors 5, 6, 7) which are already present in a conventional battery power plant. Therefore, the method according to the invention requires no or only little additional hardware.

### LIST OF REFERENCE SYMBOLS

1 battery module
2 cell arrangement
3 tank device
4 temperature sensor
5 sensor for measuring the terminal voltage
6 sensor for measuring the open-circuit voltage
7 sensor for measuring the current flowing through a battery string
8 evaluation device
9 DC-DC converter
10 control unit of a battery string
11 DC-AC converter
12 control unit of a battery string group
13 central control unit of the battery power plant

1. A method for monitoring a battery power plant comprising a plurality of battery modules which are a redox flow battery and each comprises a cell arrangement, a tank device for storing an electrolyte and pumps for supplying the electrolyte, wherein one or more battery modules electrically connected to one another in a series connection forming a battery string, wherein the battery power plant comprises a converter and a DC side of the converter is connected to the battery string such that the converter feeds a current into the battery string in order to charge or discharge associated battery modules of the one or more battery modules, and wherein the method comprises the following steps:
S1: generating a time-varying excitation current I with a base frequency f, by which at least one battery module of the one or more battery modules is excited to perform an impedance spectroscopy;
S2: time-resolved detecting the excitation current I and a response voltage V;
S3: calculating the impedance Z(ω), wherein ω=2πf; and
S4: initiating maintenance work on the at least one battery module if Re{Z(ω)} exceeds a predefined limit value,
wherein, in step S1, the excitation current I is generated using the converter, and
wherein the base frequency of the generated time-varying excitation current satisfies f≤20 Hz.

2. The method according to claim 1, further comprising detecting a temperature of the electrolyte and a flow rate of the electrolyte through the cell arrangement in the at least one battery module,
wherein the initiating maintenance work on the at least one battery module of step S4 is based on the temperature and the flow rate.

3. The method according to claim 1, further comprising detecting a state of charge in the at least one battery module,
wherein the initiating maintenance work on the at least one battery module of step S4 is based on the state of charge.

4. The method according to claim 1, wherein, in step S1, all battery modules of the battery string are excited with the time-varying excitation current I to perform the impedance spectroscopy.

5. The method according claim 1, wherein the at least one battery module comprises:
an evaluation device;
a sensor for measuring a terminal voltage V_{Klemm};
a sensor for measuring an open-circuit voltage V_{OCV}; and
a sensor for measuring the excitation current I flowing through the at least one battery module,
wherein the response voltage V satisfies V=V_{Klemm}−V_{OCV}, and
wherein step S3 is carried out by the evaluation device.
